(19) United States
(12) Patent Application Publication
(10) Pub. No.: US 2026/0156977 A1
(43) Pub. Date: Jun. 4, 2026

(54) CONDUCTIVE ELECTRODE-INTEGRATED QUANTUM EMITTER AND METHOD PRODUCING THE SAME

(71) Applicant: KOREA INSTITUTE OF SCIENCE AND TECHNOLOGY, Seoul (KR)

(72) Inventors: Hyowon MOON, Seoul (KR); Yong-Won SONG, Seoul (KR); Sofiya KARANKOVA, Seoul (KR)

(73) Assignee: KOREA INSTITUTE OF SCIENCE AND TECHNOLOGY, Seoul (KR)

(21) Appl. No.: 19/408,242

(22) Filed: Dec. 3, 2025

(30) Foreign Application Priority Data
Dec. 4, 2024 (KR) 10-2024-0178664

(51) Int. Cl. H10H 20/81; H10H 20/01; H10H 20/825; H10H 20/833

(52) U.S. Cl. CPC H10H 20/8215; H10H 20/01335; H10H 20/032; H10H 20/8252; H10H 20/833

(57) ABSTRACT

An electrode-integrated quantum emitter, according to an embodiment, may comprise: a substrate; a solid-state material located on the substrate; and an electrode formed on the solid-state material, in which the solid-state material may include defects formed in the solid-state material by adsorbates generated as a results of the reaction with a catalyst material located around the solid-state material, and the electrode may be formed by the adsorbates being formed around at least one of the substrate and the solid-state material.

### CROSS REFERENCE TO RELATED APPLICATION

The present application claims priority to Korean Patent Application No. 10-2024-0178664, Dec. 4, 2024, the entire contents of which are hereby incorporated by this reference.

### BACKGROUND OF THE INVENTION

### Field of the Invention

The disclosed embodiments relate to a technology for providing an electrode-integrated quantum emitter.

### DESCRIPTION OF GOVERNMENT-SPONSORED RESEARCH

This research was carried out with support from the Ministry of Science and ICT and the Korea Institute of Science and Technology's research operating expenses support (R&D) (main project expense), [project title: development of quantum computer (photon-atom based) technology, project identification number: 2710034012, sub-project identification number: 2E32940].

This research was carried out with support from the Ministry of Science and ICT and the individual basic research (Ministry of Science and ICT), [project title: fabrication of exciton-based circuits using local control in low-dimensional semiconductor materials, project identification number: 2710000801, sub-project identification number: 00210097].

This research was carried out with support from the Ministry of Science and ICT and the nano-material technology development, [project title: development of room-temperature-operating quantum emitter technology based on two-dimensional hexagonal boron nitride, project identification number: 2710016403, sub-project identification number: 2022M3H4A1A04096396].

### Description of the Related Art

Quantum technology leads innovative technological development such as information processing, information communication, and physical quantity measurement that surpass the limits of classical approaches by using quantum superposition, interference, entanglement, and the like. A quantum emitter, which means an emitter that emits individual photons one at a time, can deliver quantum information existing inside photons at the speed of light, and therefore has established itself as an important basic device in the field of quantum technology.

However, in order to use a quantum emitter effectively in quantum technology, controllability over the optical properties of emitted photons should be secured.

Some have proposed a method of applying an electric field to a quantum emitter so that the quantum emitter can emit photons of a desired state. Moreover, considering the influence that a quantum emitter based on a solid-state material receives from an external environment including surrounding nuclear spins, the stabilization of the quantum emitter is required to be advanced.

However, the currently proposed method forms an electrode through an additional process that begins after forming a quantum emitter, and therefore has a disadvantage in that the producing time becomes relatively long compared with the case of generating only a quantum emitter. In addition, the electrode formation process may impair the stability of the quantum emitter, and photon emission may be hindered by an opaque metal electrode.

Despite existing approaches, there remains a need for improved techniques to stabilize quantum light sources. When fabricating a quantum light source including electrodes, the fabrication steps and processing time should be reduced to levels comparable to those required for fabricating the quantum light source alone. In addition, the electrodes must be formed to be thin, transparent, and uniform so as to preserve the performance of the quantum light source.

### Documents of Related Art

Korean Registered Patent Publication No. 10-2614217 (published on December 15, 2023)

### SUMMARY OF THE INVENTION

The disclosed embodiments are directed to providing an electrode-integrated quantum emitter.

There is provided an electrode-integrated quantum emitter according to an embodiment. The electrode-integrated quantum emitter may comprise: a substrate; a solid-state material located on the substrate; and an electrode formed on the solid-state material, in which the solid-state material may include defects formed in the solid-state material by adsorbates generated by reaction with a catalyst material located around the solid-state material, and the electrode may be formed by the adsorbates being formed around at least one of the substrate and the solid-state material.

The electrode may be formed by the adsorbates being formed on a surface of the solid-state material as a result of the reaction between the compound including the adsorbates and the catalyst material in an environment at a preset temperature or higher.

The solid-state material may be a two-dimensional material including hexagonal boron nitride, and the adsorbates may form a conductive material including graphene.

The adsorbates may be a nonlinear conductive material including graphene.

The catalyst material may be a non-metal catalyst including gamma-aluminum oxide, the compound may be a compound including a carbon precursor, the defects may be carbon-related defects formed by the adsorbates contacting a surface of the solid-state material as a result of the reaction between the compound attached to the catalyst material and the catalyst material, and the electrode may be a transparent thin-film electrode formed in which the adsorbates are formed on the surface of the solid-state material as a result of the reaction between the compound attached to the catalyst material and the catalyst material.

The defects and the electrode may be formed at a point in time close to or the same as a point in time at which the adsorbates contact the solid-state material.

The electrode may be formed by adjusting a thickness of the solid-state material.

The electrode may be formed by adjusting at least one of a temperature of the substrate and a compositional ratio of the adsorbates included in the compound.

The solid-state material may have undergone electron-beam processing before the defects are formed.

The catalyst material may be located to face the solid-state material.

The catalyst material may be located to face the solid-state material in a size equal to or greater than at least one of the substrate and the solid-state material.

The catalyst material may be located at a position and/or size determined in relation to the solid-state material.

There is provided a method of producing an electrode-integrated quantum emitter, according an embodiment. The method may comprise: locating a solid-state material on a substrate; locating a catalyst material around the solid-state material; spraying a compound around at least one of the solid-state material and the catalyst material; forming, in the solid-state material, defects related to adsorbates generated by reaction of the compound with the catalyst material through the spraying; and forming the electrode as the adsorbates are formed around at least one of the substrate and the solid-state material through the spraying.

The method may further comprise: heating at least one of the substrate and the solid-state material, and wherein the forming of the electrode comprises forming the adsorbates on a surface of the solid-state material by reacting the compound with the catalyst material in an environment at a preset temperature or higher.

The solid-state material may be a two-dimensional material including hexagonal boron nitride, and the adsorbates may form a conductive material including graphene.

The adsorbates may be a nonlinear conductive material including graphene.

The catalyst material may be a non-metal catalyst including gamma-aluminum oxide, the compound may be a compound including a carbon precursor, the defects may be carbon-related defects formed by the adsorbates contacting a surface of the solid-state material as a result of the reaction between the compound attached to the catalyst material and the catalyst material, and the electrode may be a transparent thin-film electrode in which the adsorbates are formed on the surface of the solid-state material as a result of the reaction between the compound attached to the catalyst material and the catalyst material.

The defects and the electrode may be formed at a point in time close to or the same as a point in time at which the adsorbates contact the solid-state material.

The forming of the electrode may comprise: forming the electrode by adjusting a thickness of the solid-state material.

The forming of the electrode may comprise: forming the electrode by adjusting at least one of a temperature of the substrate and a compositional ratio of the adsorbates included in the compound.

The method may further comprise: performing electron-beam processing on the solid-state material before forming the defects in the solid-state material.

The locating may comprise: locating the catalyst material to face the solid-state material.

The locating may comprise: locating the catalyst material to face the solid-state material in a size equal to or greater than at least one of the substrate and the solid-state material.

The locating may comprise: locating the catalyst material at a position and/or size determined in relation to the solid-state material.

The disclosed embodiments allow conductive electrode made of adsorbed atoms, which are decomposed by reacting with a catalyst material, to contact the surface of a solid-state material and grow on the surface while simultaneously penetrating into the material and forming a defect structure, whereby a quantum emitter and an electrode can be simultaneously generated.

The disclosed embodiments use conductive electrode made of adsorbed atoms to grow graphene on a solid-state material to synthesize an electrode and thereby synthesize a thin-film electrode, whereby an absorption effect of light that occurred due to a thick electrode or a metal electrode located around a quantum emitter can be avoided.

The disclosed embodiments use hexagonal boron nitride as a solid-state material, whereby the entire quantum emitter in which an electrode is synthesized can be transferred to another substrate, whereby the diversity of substrates and the flexibility of fabrication processes can be enhanced.

The disclosed embodiments can adjust the position and size of a catalyst material to adjust the position and distribution area of adsorbed atoms that will be sprayed onto a quantum emitter, whereby the position and size in which an electrode is synthesized on the quantum emitter can be adjusted.

The disclosed embodiments perform electron-beam processing on a solid-state material to modulate the emission characteristics of a quantum emitter, whereby a quantum emitter having desired optical properties can be produced.

### BRIEF DESCRIPTION OF THE DRAWINGS

FIG. 1 is a diagram for describing an electrode-integrated quantum emitter according to an embodiment.

FIGS. 2A to 2C are diagrams illustrating results of analyzing characteristics of a solid-state material before a first process treatment.

FIGS. 3A to 3C are diagrams illustrating results of analyzing characteristics of a solid-state material after the first process treatment.

FIGS. 4A to 4C are diagrams illustrating experimental results of analyzing characteristics of a solid-state material after a second process treatment.

FIGS. 5A and 5B are diagrams respectively illustrating spectra of the substrate and solid-state material before and after the first process treatment.

FIGS. 6A and 6B are diagrams respectively illustrating spectra of a substrate or a solid-state material before and after the first process treatment as a function of the thickness of the solid-state material.

FIGS. 7A and 7B are diagrams respectively illustrating an optical microscope image and an AFM image of a solid-state material before and after the first process treatment.

FIG. 8 is a diagram illustrating changes in brightness of an electrode-integrated quantum emitter over time according to an embodiment.

FIG. 9 is a flowchart for describing a method of producing an electrode-integrated quantum emitter according to an embodiment.

### DETAILED DESCRIPTION OF THE INVENTION

Hereinafter, specific exemplary embodiments of an embodiment will be described with reference to the drawings. The following detailed description is provided to assist in the comprehensive understanding of a producing method described in the present specification. However, the exemplary embodiments are provided only for illustrative purpose, and the present invention is not limited thereto.

In addition, in the description of the exemplary embodiments, the specific descriptions of publicly known technologies related with the present invention will be omitted when it is determined that the specific descriptions may unnecessarily obscure the subject matter of the exemplary embodiments. In addition, the ordinal numbers (e.g., first, second, etc.) used for the description in the embodiments are merely identification symbols for distinguishing one component from another component.

The terms used herein are defined considering the functions in the present invention and may vary depending on the intention, usual practice, or the like of a user or an operator. Therefore, the definitions should be made based on the entire contents of the present specification. The terms used in the detailed description are provided only for describing the exemplary embodiments and should not be restrictive. Unless explicitly used otherwise, singular expressions include plural expressions thereof. In the present specification, the terms “comprises,” “comprising,” “includes,” “including,” “containing,” “has,” “having” or other variations thereof are provided to indicate specific components, numbers, steps, operations, elements, and some or combinations thereof, and it should not be construed to exclude the presence or possibility of one or more other components, numbers, steps, operations, elements, and some or combinations thereof other than those disclosed.

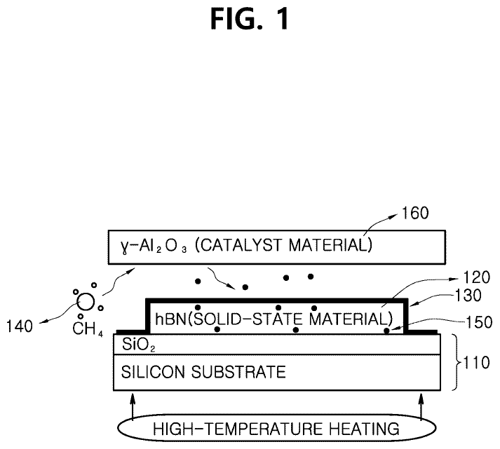

FIG. 1 is a diagram for describing an electrode-integrated quantum emitter according to an embodiment.

With reference to FIG. 1, an electrode-integrated quantum emitter according to an embodiment includes a substrate, a solid-state material, and an electrode.

The substrate is a structure located below the solid-state material to support the solid-state material. It is preferable that the substrate be composed of a material having high thermal conductivity in order to dissipate heat to other components stacked on the substrate. It is preferable that the substrate be composed of a material having excellent heat resistance to stably ensure mechanical stability even under high-temperature conditions. Preferably, the substrate may be a silicon-based semiconductor substrate.

The solid-state material is located on the substrate. The solid-state material may be stacked on the substrate to receive lower support. In this case, the solid-state material, as a two-dimensional material, may mean a material having a thin thickness at the atomic level. For example, the solid-state material may be a two-dimensional material composed of hexagonal boron nitride.

The electrode is synthesized around at least one of the substrate and the solid-state material. The electrode is formed from adsorbate generated through a reaction between a catalyst material disposed near the solid-state material and a compound. Specifically, the electrode may be synthesized by adsorbed atoms being formed on a surface of the solid-state material when a catalyst material located around the solid-state material reacts with a gas-form compound and the compound is decomposed into adsorbed atoms. For example, the electrode may be synthesized by the adsorbed atoms directly growing while being stacked on the surface of the solid-state material.

In this case, the compound, as a carbon precursor, is sprayed in a methane (CH₄) gas form around at least one of the solid-state material and the catalyst material, and is decomposed into adsorbed atoms by reacting with the catalyst material. Here, the adsorbed atoms, as carbon adsorbed atoms, may be including graphene, for example.

The adsorbed atoms contact the surface of the solid-state material to generate defects in the solid-state material, and the defects may reflect characteristics of the adsorbed atoms. Depending on heat applied to the substrate, the defects may move from the surface into the inside of the solid-state material. The solid-state material in which defects are generated can perform a function of a quantum emitter.

On the other hand, the electrode may be synthesized by the adsorbed atoms being formed on the surface of the solid-state material. In particular, when graphene is deposited on the surface of the solid-state material, it may be grown to form the electrode. In this case, graphene may be a single layer or multiple layers, and since the light absorption of each layer is only about 2.3%, it can be used as a transparent thin-film electrode.

Here, the catalyst material, as a ceramic catalyst including gamma-aluminum oxide, may be a non-metal catalyst. The catalyst material may be located on a surface facing a solid-state material so that a sprayed compound is decomposed into adsorbed atoms and deposited on a surface of the substrate or the solid-state material. Here, a reaction between the compound and the catalyst material may be performed in a high-temperature environment.

In this case, a point in time at which the adsorbed atoms contact a surface of the solid-state material to form defects, and a point in time at which the adsorbed atoms are deposited on the surface of the solid-state material to synthesize an electrode, may begin simultaneously or concurrently. From this, an electrode-integrated quantum emitter according to an embodiment has an advantage in that the producing process is simplified by simultaneously proceeding with electrode synthesis on a quantum emitter while generating the quantum emitter.

Meanwhile, for active modulation of an electrode-integrated quantum emitter according to an embodiment, additional processes may be added to the substrate, the solid-state material, or the catalyst material.

For example, the substrate may have controlled heat capacity during the heating process, so that the degree of electrode synthesis may be adjusted. In another example, the solid-state material may have electron-beam processing before spraying the compound. Through this, an electrode-integrated quantum emitter may modulate an emission wavelength. In another example, the degree of electrode synthesis may be adjusted by adjusting a compositional ratio of the compound.

In another example, the catalyst material may have a determined position and/or size adjusted in relation to the solid-state material, so that a position and/or size in which the electrode is synthesized on the solid-state material may be determined. Particularly, the catalyst material may be located to face the solid-state material in a size of at least one of the substrate and the solid-state material, so that a large-area electrode may be synthesized over an entire surface of the solid-state material.

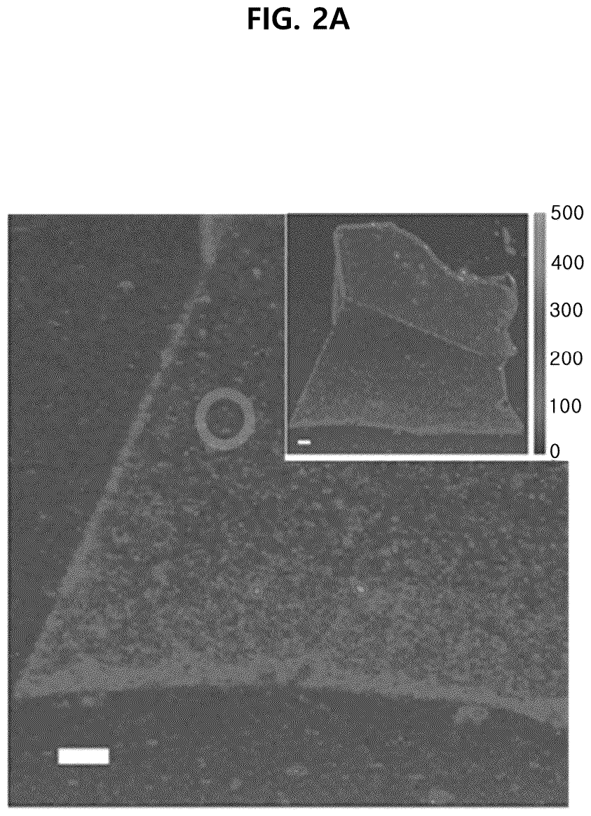

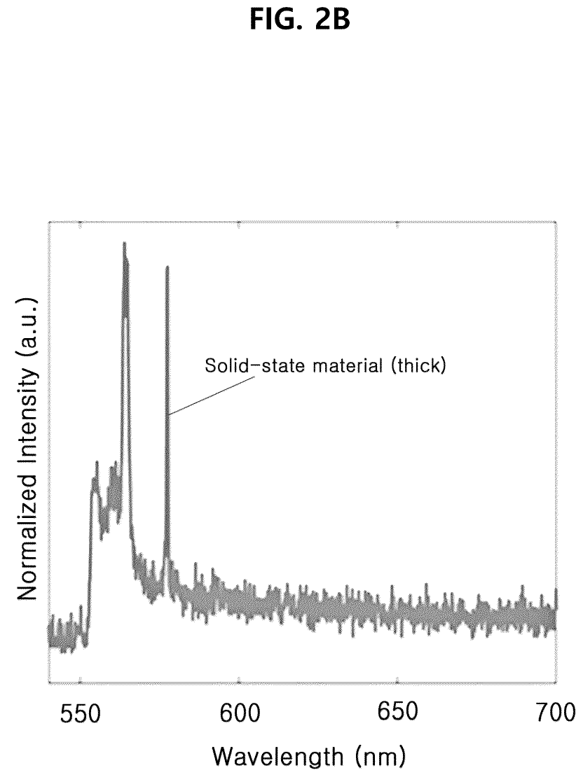

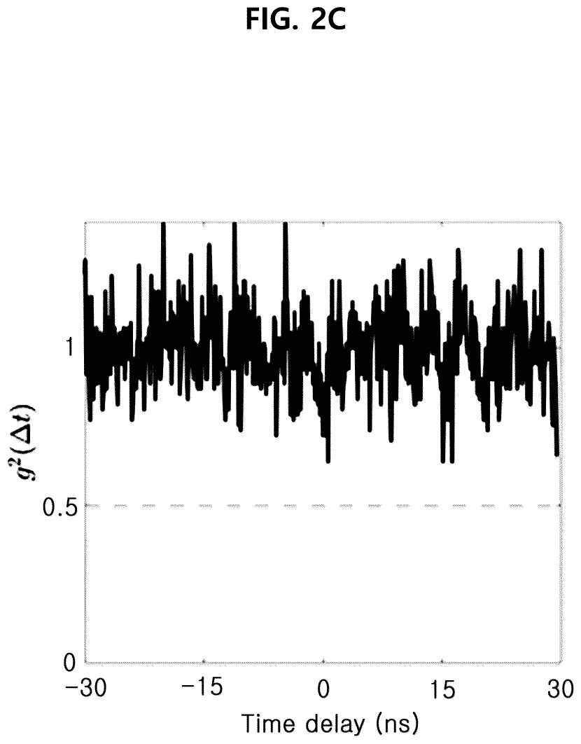

FIGS. 2A to 2C are diagrams illustrating results of analyzing characteristics of a solid-state material before a first process treatment.

Here, the first process treatment may mean a process of spraying a compound at a preset temperature or higher. That is, the solid-state material may be interpreted as having no defects and having no adsorbed atoms synthesized on the surface.

FIG. 2A is a diagram illustrating a PL map of the solid-state material before the first process, FIG. 2B is a diagram illustrating a PL spectrum of the solid-state material before the first process, and FIG. 2C is a diagram illustrating a second-order correlation function from the solid-state material before the first process.

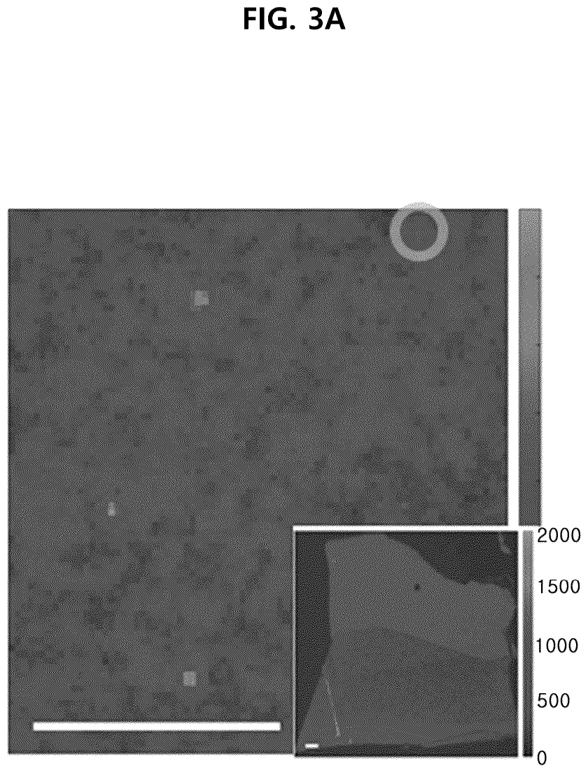

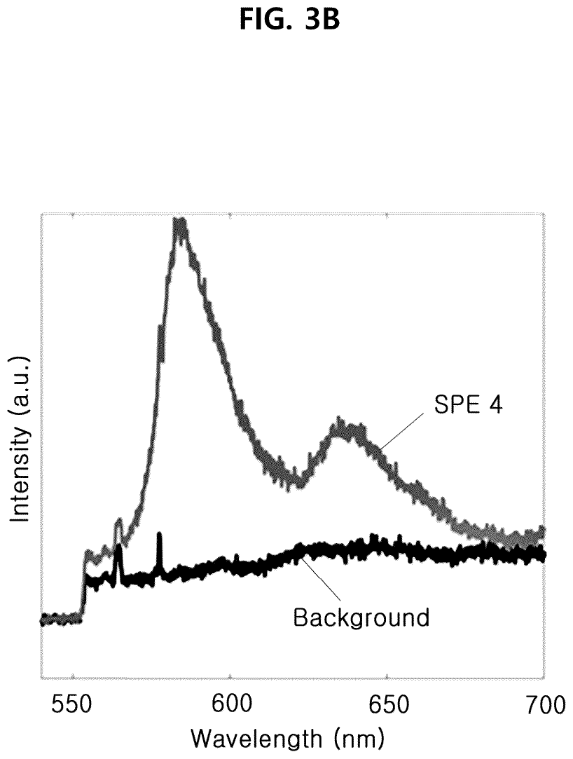

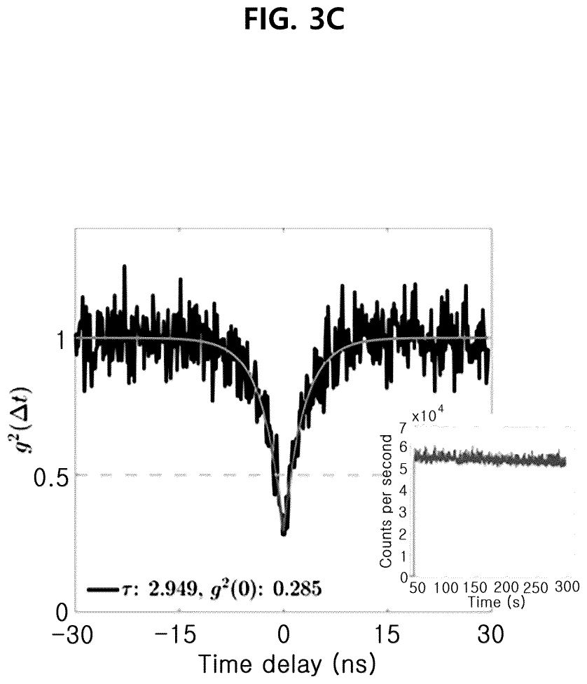

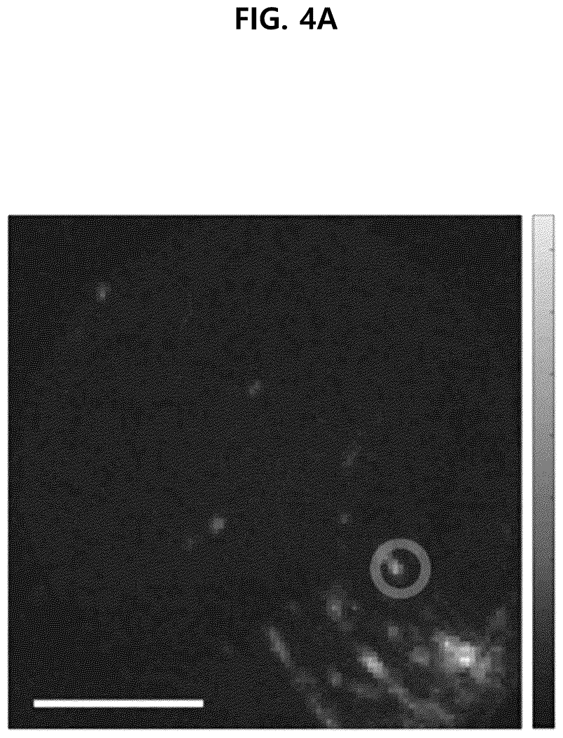

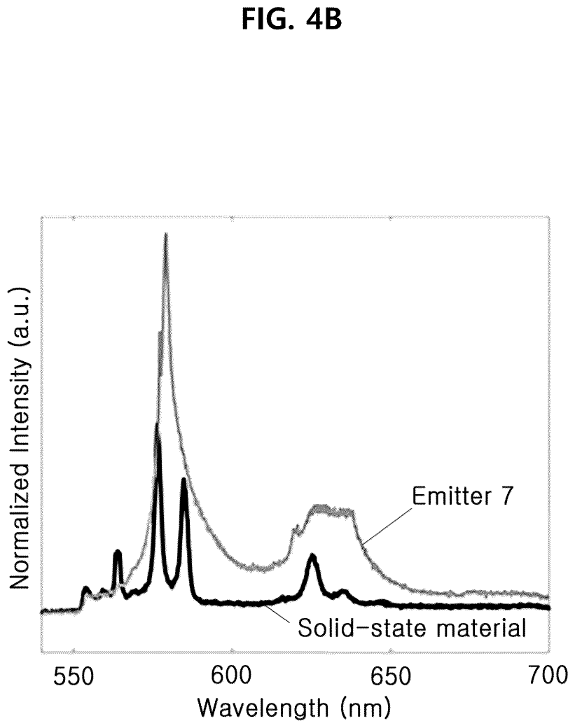

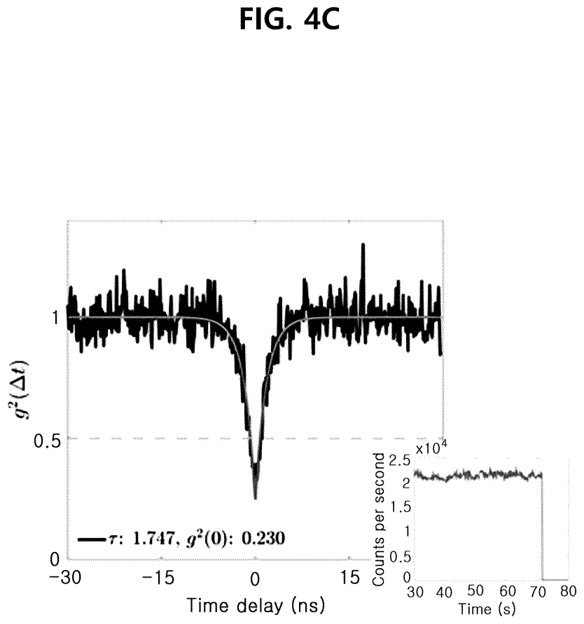

FIGS. 2A to 2C are confirmed to not exhibit characteristics of a general quantum emitter, unlike FIGS. 3A to 3C and FIGS. 4A to 4C described later.

FIGS. 3A to 3C are diagrams illustrating results of analyzing characteristics of a solid-state material after the first process treatment.

Here, the first process is the same as the process described in FIGS. 2A to 2C, and overlapping descriptions will be omitted.

FIGS. 3A to 3C illustrate a solid-state material including defects intended in this specification, and it is expected to perform a function of a quantum emitter. Hereinafter, FIGS. 3A to 3C describe characteristics in which the solid-state material functions as a quantum emitter after the first process treatment.

FIG. 3A is a diagram illustrating a PL map of the solid-state material after the first process, FIG. 3B is a diagram illustrating a PL spectrum of the solid-state material after the first process, and FIG. 3C is a diagram illustrating a second-order correlation function of the quantum emitter in the solid-state material after the first process.

In FIG. 3A, the PL map shows that the emission region noticeably increases compared to FIG. 2A, showing defects generated in the solid-state material.

In FIG. 3B, the PL spectrum shows peaks in a new wavelength band that could not be identified in FIG. 2A.

The new peaks occur roughly at 585 nm and 630 nm, and are peaks generated in wavelength bands completely different from Raman signals exhibited by the substrate (e.g., Si/SiO₂) and the solid-state material (hexagonal boron nitride).

In FIG. 3C, the second-order correlation function shows a characteristic in which the second-order correlation function decreases as time delay approaches zero, showing characteristics of a general quantum emitter.

FIGS. 4A to 4C are diagrams illustrating experimental results of analyzing characteristics of a solid-state material after a second process treatment.

Here, the second process is a process in which electron-beam processing of the solid-state material before the first process has been completed, and overlapping descriptions will be omitted.

FIG. 4A is a diagram illustrating a PL map of the solid-state material after the second process, FIG. 4B is a diagram illustrating a PL spectrum of the solid-state material after the second process, and FIG. 4C is a diagram illustrating a second-order correlation function of the quantum emitter in the solid-state material after the second process.

With reference to FIGS. 4A and 4C, similarly to the characteristics illustrated in FIGS. 3A and 3C, the solid-state material that has undergone the second process is confirmed to perform a function of a quantum emitter.

A difference is shown in FIG. 4B. With reference to FIG. 3B, it is confirmed that the emission bandwidth of the solid-state material becomes narrower according to the PL spectrum. From this, an electrode-integrated quantum emitter according to an embodiment may be modulated to have a narrower emission bandwidth through the second process.

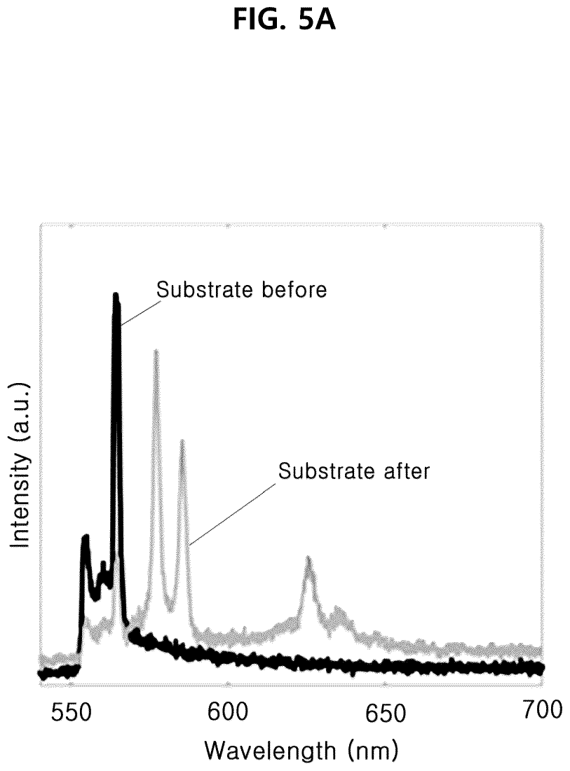

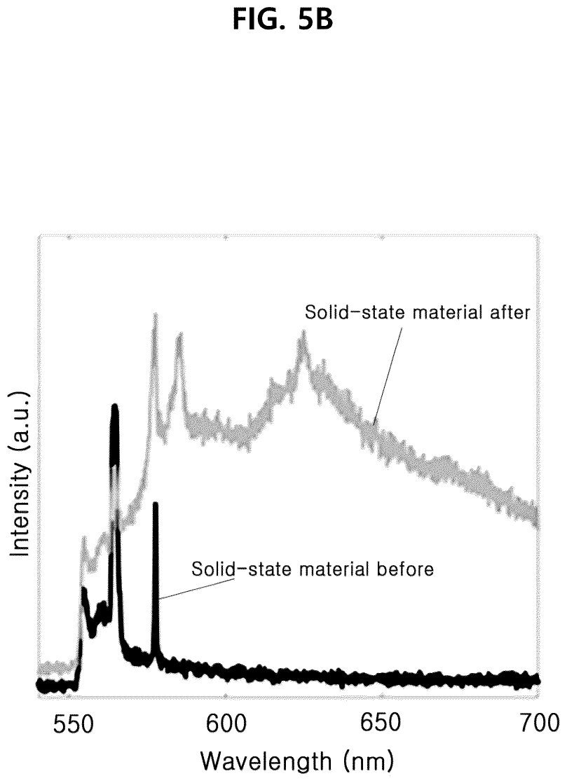

FIGS. 5A and 5B are diagrams respectively illustrating spectra of the substrate and the solid-state material before and after the first process treatment.

In FIG. 5A, peaks related to Raman signals appearing from the substrate (e.g., Si/SiO₂) and the graphene located on top of the substrate are illustrated.

In FIG. 5B, peaks related to Raman signals appearing from the substrate (e.g., Si/SiO₂), the solid-state material (hexagonal boron nitride), and the graphene located on top of the substrate are illustrated.

In both FIG. 5A and 5B, new peak bands (in gray) appear after the first process treatment. Specifically, signals at 577 nm, 585 nm, and 626 nm are known as Raman spectroscopic signals of graphene. The solid-state material in which the first process treatment has been completed may be evaluated as having graphene successfully deposited.

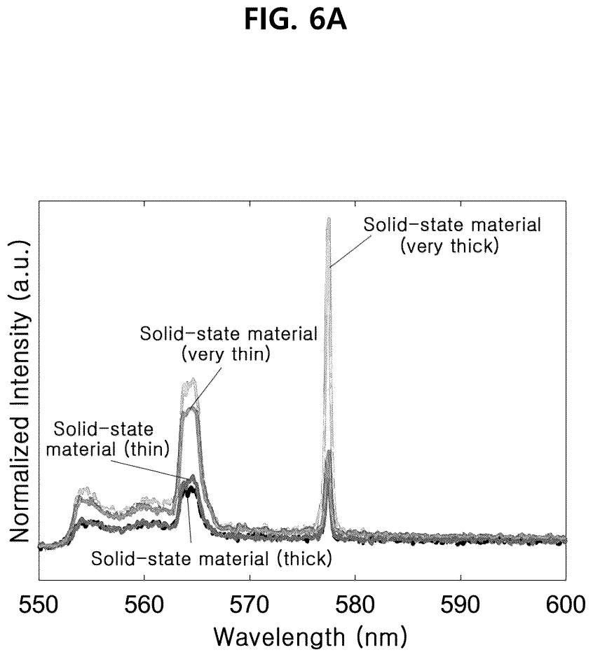

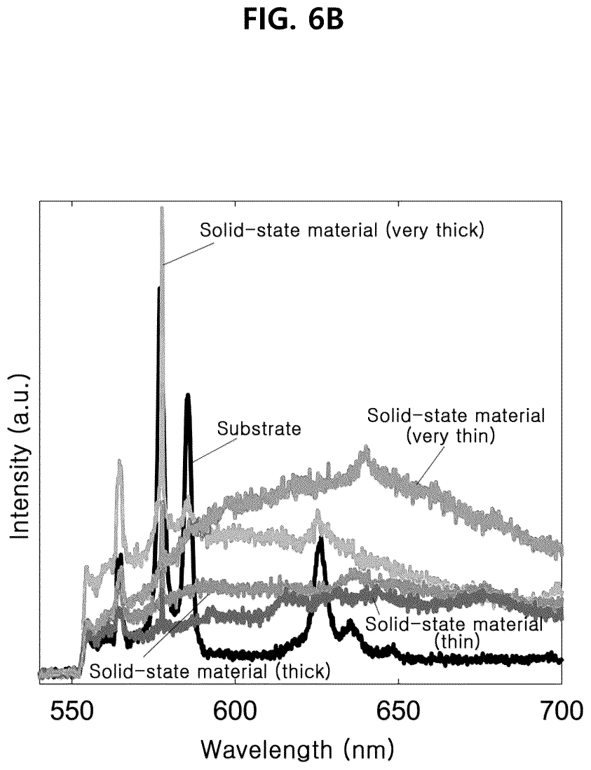

FIGS. 6A and 6B are diagrams respectively illustrating spectra of a substrate or a solid-state material before and after the first process treatment, according to the thickness of the solid-state material.

In FIG. 6A, the spectrum of the solid-state material before the first process treatment does not show meaningful change according to the thickness of the solid-state material. The peaks in this case are Raman scattering signals of Si/SiO₂ used as the substrate, and hexagonal boron nitride used as the solid-state material.

In FIG. 6B, the spectrum of the substrate or the solid-state material after the first process treatment shows meaningful change according to the thickness of the solid-state material. In particular, in a wavelength band corresponding to Raman scattering signals related to graphene, it can be confirmed that the PL brightness of the solid-state material changes meaningfully according to a thickness of the solid-state material.

That is, an electrode-integrated quantum emitter according to an embodiment can have characteristics modulated according to a thickness of the solid-state material.

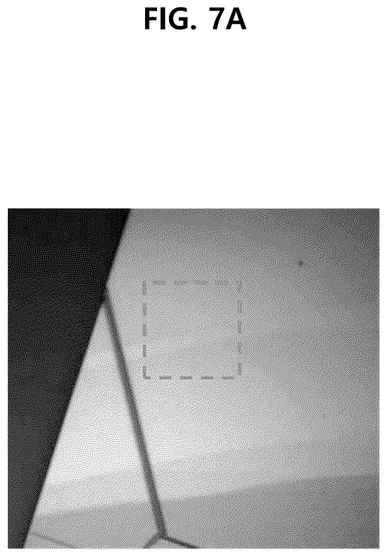

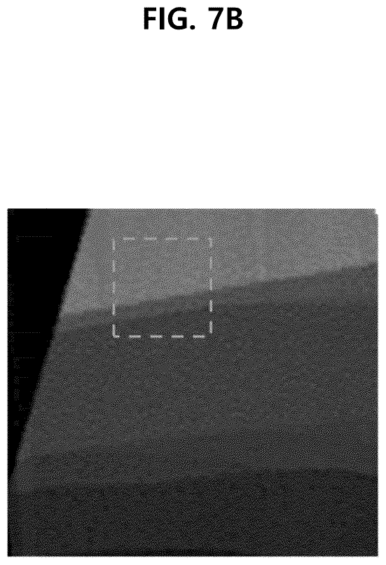

FIGS. 7A and 7B are diagrams respectively illustrating an optical microscope image and an AFM image of a solid-state material before and after the first process treatment.

FIGS. 7A and 7B are an optical microscope image and an AFM image, respectively, of hexagonal boron nitride on which graphene is synthesized through the first process, and it can be confirmed that colors appear differently depending on a thickness of hexagonal boron nitride.

That is, an electrode-integrated quantum emitter according to an embodiment can have characteristics modulated according to a thickness of the solid-state material.

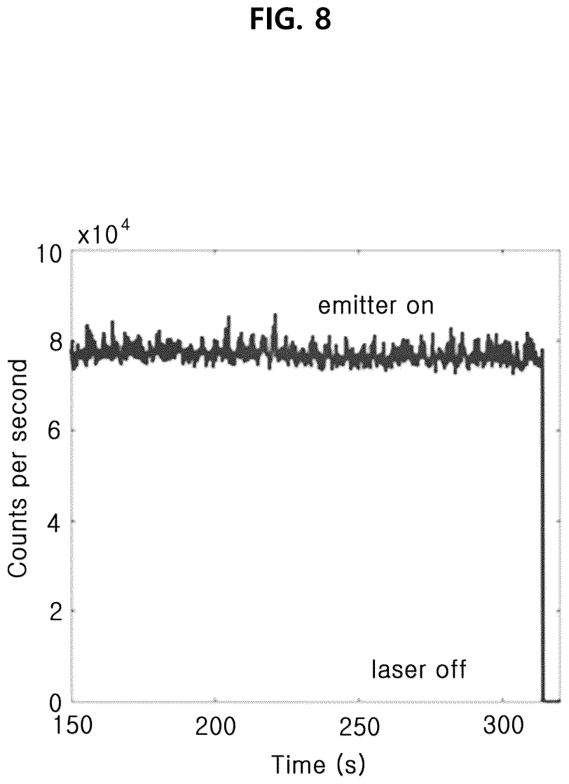

FIG. 8 is a diagram illustrating a brightness change of an electrode-integrated quantum emitter according to an embodiment over time.

In FIG. 8, a brightness of the electrode-integrated quantum emitter according to an embodiment remains almost the same level below a certain error level for 10 minutes or more. From this, the electrode-integrated quantum emitter according to an embodiment can be confirmed to be stabilized through the synthesized electrode.

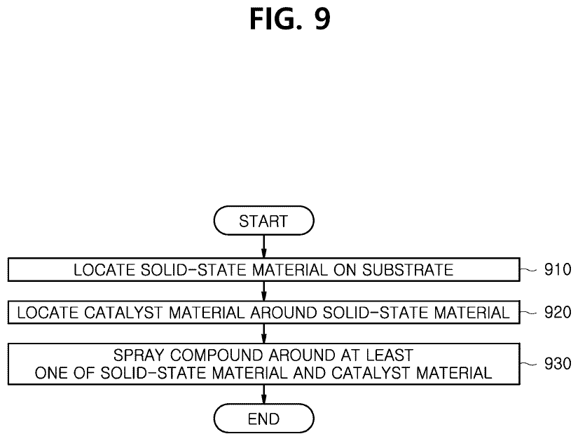

FIG. 9 is a flowchart for describing a method of producing an electrode-integrated quantum emitter according to an embodiment.

With reference to FIG. 9, a method of producing an electrode-integrated quantum emitter may be performed by an electrode-integrated quantum emitter device that produces the electrode-integrated quantum emitter of FIG. 1.

First, the electrode-integrated quantum emitter device locates a solid-state material on a substrate (910).

Thereafter, the electrode-integrated quantum emitter device locates a catalyst material around the solid-state material (920).

Thereafter, the electrode-integrated quantum emitter device sprays a compound around at least one of the solid-state material and the catalyst material (930).

In this case, the solid-state material, as a result of spraying, includes defects formed in the solid-state material by adsorbates generated by reaction of the compound with the catalyst material.

In this case, the electrode is synthesized as the adsorbates are formed around at least one of the substrate and the solid-state material as a result of spraying.

Meanwhile, although the method of FIG. 9 is described in multiple steps, at least some of the steps may be performed in a different order, combined with other steps to be performed together, omitted, broken down into detailed steps, or one or more additional steps not illustrated may be added and performed.

The present invention has been described above with reference to the embodiments illustrated in the drawings, which are just for illustration, and those skilled in the art will understand that various modifications and variations of the embodiments are possible. However, such modifications should be considered to be within the technical protection scope of the present invention. Accordingly, the true technical protection scope of the present invention should be determined by the technical teachings of the appended claims.

### DESCRIPTION OF REFERENCE NUMERALS

100: Electrode-integrated quantum emitter
110: Substrate
120: Solid-state material
130: Electrode
140: Compound
150: Adsorbed atoms
160: Catalyst material

What is claimed is:

1. An electrode-integrated quantum emitter, comprising:
a substrate;
a solid-state material located on the substrate; and
an electrode formed on the solid-state material,
wherein the solid-state material includes defects formed in the solid-state material by adsorbates generated by reaction with a catalyst material located around the solid-state material, and
wherein the electrode is formed by the adsorbates being formed around at least one of the substrate and the solid-state material.

2. The electrode-integrated quantum emitter of claim 1, wherein the electrode is formed by the adsorbates being formed on a surface of the solid-state material as a result of the reaction between the compound including the adsorbates and the catalyst material in an environment at a preset temperature or higher.

3. The electrode-integrated quantum emitter of claim 2, wherein the solid-state material is a two-dimensional material including hexagonal boron nitride, and the adsorbates form a conductive material including graphene.

4. The electrode-integrated quantum emitter of claim 3, wherein the catalyst material is a non-metal catalyst including gamma-aluminum oxide,
the compound is a compound including a carbon precursor,
the defects are carbon-related defects formed by the adsorbates contacting a surface of the solid-state material as a result of the compound sprayed onto the catalyst material reacting with the catalyst material, and
the electrode is a transparent thin-film electrode in which the adsorbates are formed on the surface of the solid-state material as a result of the compound sprayed onto the catalyst material reacting with the catalyst material.

5. The electrode-integrated quantum emitter of claim 1, wherein the defects and the electrode are formed at a point in time close to or the same as a point in time at which the adsorbates contact the solid-state material.

6. The electrode-integrated quantum emitter of claim 1, wherein the electrode is formed by adjusting a thickness of the solid-state material.

7. The electrode-integrated quantum emitter of claim 2, wherein the electrode is formed by adjusting at least one of a temperature of the substrate and a compositional ratio of the adsorbates included in the compound.

8. The electrode-integrated quantum emitter of claim 1, wherein the solid-state material has undergone electron-beam processing before the defects are formed.

9. The electrode-integrated quantum emitter of claim 1, wherein the catalyst material is located to face the solid-state material.

10. The electrode-integrated quantum emitter of claim 1, wherein the catalyst material is located at a position and/or size determined in relation to the solid-state material.

11. A method of producing an electrode-integrated quantum emitter, the method comprising:
locating a solid-state material on a substrate;
locating a catalyst material around the solid-state material;
spraying a compound around at least one of the solid-state material and the catalyst material;
forming, in the solid-state material, defects related to adsorbates generated by reaction of the compound with the catalyst material through the spraying; and
forming the electrode as the adsorbates are formed around at least one of the substrate and the solid-state material through the spraying.

12. The method of claim 11, further comprising:
heating at least one of the substrate and the solid-state material,
wherein the forming of the electrode comprises forming the adsorbates on a surface of the solid-state material as a result of the reaction between the compound and the catalyst material in an environment at a preset temperature or higher.

13. The method of claim 12, wherein the solid-state material is a two-dimensional material including hexagonal boron nitride, and the adsorbates form a conductive material including graphene.

14. The method of claim 13, wherein the catalyst material is a non-metal catalyst including gamma-aluminum oxide,
the compound is a compound including a carbon precursor,
the defects are carbon-related defects formed by the adsorbates contacting a surface of the solid-state material as a result of the compound sprayed onto the catalyst material reacting with the catalyst material, and
the electrode is a transparent thin-film electrode in which the adsorbates are formed on the surface of the solid-state material as a result of the reaction between the compound attached to the catalyst material and the catalyst material.

15. The method of claim 11, wherein the defects and the electrode are formed at a point in time close to or the same as a point in time at which the adsorbates contact the solid-state material.

16. The method of claim 11, wherein the forming of the electrode comprises:
forming the electrode by adjusting a thickness of the solid-state material.

17. The method of claim 12, wherein the forming of the electrode comprises:
forming the electrode by adjusting at least one of a temperature of the substrate and a compositional ratio of the adsorbates included in the compound.

18. The method of claim 11, further comprising:
performing electron-beam processing on the solid-state material before forming the defects in the solid-state material.

19. The method of claim 11, wherein the locating comprises:
locating the catalyst material to face the solid-state material.

20. The method of claim 11, wherein the locating comprises:
locating the catalyst material at a position and/or size determined in relation to the solid-state material.
